(19) United States
(12) Patent Application Publication
(10) Pub. No.: US 2009/0311878 A1
(43) Pub. Date: Dec. 17, 2009

(54) METHOD FOR DEPOSITING A DIELECTRIC MATERIAL

(75) Inventors: Shin-Yu Nieh, Taipei City (TW); Tsai-Yu Huang, Banciao City (TW); Chun-I Hsieh, Hsinchu City (TW)

Correspondence Address: VOLPE AND KOENIG, P.C., UNITED PLAZA, SUITE 1600, 30 SOUTH 17TH STREET, PHILADELPHIA, PA, 19103, US

(73) Assignee: NANYA TECHNOLOGY CORP., Tao-Yuan Hsien (TW)

(21) Appl. No.: 12/198,715

(22) Filed: Aug. 26, 2008

(30) Foreign Application Priority Data
Jun. 12, 2008 (TW) 097121995

(51) Int. Cl. H01L 21/31

(52) U.S. Cl. 438/785; 257/E21.129

(57) ABSTRACT

A depositing method for a dielectric material is provided, where the dielectric material has the first and the second primary elements, and a single precursor includes the first and the second primary elements. The depositing method includes pulsing the single precursor, purging a redundant part of the single precursor, pulsing an oxidant for oxidizing the single precursor, and purging a redundant part of the oxidant.

### FIELD OF THE INVENTION

The present invention relates to a method for depositing a dielectric material, and more particularly to a dielectric material depositing method.

### BACKGROUND OF THE INVENTION

The dielectric materials are mostly formed via the deposition process in the semiconductor field. If the high dielectric material is applied to the semiconductor, the method of atomic layer deposition (ALD) combined with the pulse-purge method are used to deposit the dielectric materials. At first, the materials are pulsed on the substrate surface where the materials are to be deposited, and then the redundant materials are purged and removed from the substrate.

Usually, the dielectric materials are not directly applied to the substrate, but a chemical compound is used as a precursor. After then, the oxidation or reduction reaction (usually the oxidation) is processed to obtain the final dielectric material.

Please refer to FIG. 1, which is the schematic diagram showing the pulse-purge deposition method. At first, the pulse process proceeds in step (a). The compound M is pulsed into the reaction chamber for inducing the chemical absorption until the saturation is reached on the surface of substrate 1, wherein the compound M is composed of elements m1 and m2. Then step (b) is in process. The redundant compound M, which is not adsorbed to the substrate 1, is purged. In step (c), an oxidation is in process. An oxidant O is introduced into the reaction chamber to react with the compound M adsorbed on the substrate 1. The oxidant O is composed of the elements o1 and o2. After the introduction of the oxidant O, oxidation reaction occurs. Of course, the substrate 1 may be heated to facilitate the oxidation reaction, when necessary. During the oxidation reaction, the compound M is combined with the oxidant O to form a new compound MO. The elements m1, m2, o1, and o2 may be combined to form a new by-product O′. Finally, the purge process proceeds in step (d). The redundant oxidant O and the compound O′ are purged. The new compound MO is the desired dielectric material, and the deposition procedure is completed. These pulse-purge processes can also be used in a Metal-Organic Chemical Vapor Deposition (MOCVD). In addition, the thickness of the deposited layer is around the scale of atomic thickness, and therefore this method is also called Atomic Layer Deposition (ALD). From the above description and FIG. 1, depositing only one dielectric material requires two pulse processes and two purge processes. To sum up, the precursor is pulsed, then the redundant precursor is purged, after then the oxidant is pulsed, and finally the redundant oxide and other by-products are purged.

Please refer to FIG. 2, which is the timing diagram of the pulse-purge deposition method, where the X-axis shows the actions and the related compounds; while the Y-axis indicates the time. Therefore, by referring to FIGS. 1 and 2, it is noted that the actions from the top to the bottom in the axis of the ordinate in FIG. 2 are listed as follows: step (a): pulsing the compound M; step (b): purging compound M; step (c): pulsing oxidant O; and step (d): purging the compound O and by-products. From the perspective of time, pulsing the compound M in step (a) corresponds to the time period a; purging compound M in step (b) corresponds to the time period b; pulsing oxidant O in step (c) corresponds to the time period c; and purging the compound O and by-products in step (d) corresponds to the time period d. Not until is step (d) finished, the entire deposition procedure is completed. Thus, the combination of the time periods a, b, c and d forms a complete deposition cycle. It is noted from the above that the complete deposition process for a whole cycle takes considerable time.

Please refer to FIG. 3, which is the time diagram of the conventional pulse-purge deposition method, where the Y-axis shows the action contents; while the X-axis indicates the timing. The actions from the top to the bottom in the Y-axis in FIG. 3 are listed as follows: action (1): pulsing the first precursor; action (2): purging; action (3): pulsing oxidant O; and action (4): pulsing the second precursor. From the view of the X-axis, action (1) is performed in the time period T1; action (2) is performed in the time period T2; action (3) is performed in the time period T3; action (2) is performed in the time period T4, action (4) is performed in the time period T5, action (2) is performed in the time period T6, action (3) is performed in the time period T7, and action (2) is performed in the time period T8. Depending on the requirements of the thickness and the ratio between the first primary element and the second primary element, the time periods from T1 to T4 can be repeated for m times, and the time periods of T5 to T8 can be repeated for n times so that the times of m and n will respectively affect the values, i.e. volume, mass, etc., of the first primary element and the second primary element in the dielectric material as well as the ratio between the first primary element and the second primary element. The time periods from T1 to T8 forms a complete technical cycle, CL1. The detail is explained as follow.

Please refer to FIG. 3 again. Since the dielectric material contains only one single element, the electrical characteristics and the dielectric constants obtained are not sufficient enough, a theory of combining two materials as the dielectric material is introduced so as to improve the dielectric constant and to improve the electric characteristics. Since two elements are usually required, the two precursors, each of which contains the respective one of the two required elements, are required to go through the oxidation reactions for obtaining the dielectric material with the desired high dielectric constant. Therefore, FIG. 3 demonstrates the pulse-purge deposition processes by using two precursors and the required oxidation reactions. In detail, form the view of the X-axis (time) axis, the whole dielectric material is formed as the following descriptions. At first, in the time period T1, action (1) is performed by pulsing the first precursor to deposit the first precursor on a substrate which usually contains deep trench (or stacked) structure. Then, in the time period T2, action (2) is performed by purging, i.e. purging the redundant first precursor from the deep trench (or stacked) structure. In the time period T3, action (3) is performed by pulsing the oxidant. In the time period T4, the action (2) is performed by purging, i.e. purging the redundant oxidant and by-products. Then, in the time period T5, action (4) is performed by pulsing the second precursor to deposit the second precursor on the substrate, which usually contains deep trench (or stacked) structure. After that, in the time period T6, action (2) is performed by purging, i.e. purging the redundant second precursor from the deep trench (or stacked) structure. In the time period T7, action (3) is performed by pulsing the oxidant. Finally, in the time period T8, action (2) is performed by purging, i.e. purging the redundant oxidant and side products.

From the above description, it can be seen that since two precursors are used, totally four pulse-purge processes are required, i.e. the pulse and purge processes for the first precursor, the pulse and purge processes for the oxidant in the first time, the pulse and purge processes for the second precursor, and the pulse and purge processes for the oxidant in the second time. The whole process takes about three minutes, which is not short enough for the semiconductor industry, which continuously pursues larger mass production and higher production efficiency. Furthermore, since several actions are required, the risk of failure is increased simultaneously. Consequently, reducing the failure risk and increasing the yield rate become important issues in this industry.

Therefore, in the current semiconductor industry, the improvement for shortening the production time of the dielectric materials and raising the yield rate is imperiously required.

In order to eliminate the drawbacks of the conventional techniques, the new concepts and the solutions are proposed in the present invention so as to solve the above-mentioned problems. The present invention is described below.

### SUMMARY OF THE INVENTION

The present invention provides a method for depositing a dielectric material. The complete processing time for depositing the dielectric materials is much shortened, as compared with the conventional technique.

In accordance with one aspect of the present invention, a precursor for manufacturing a dielectric material including a compound Hf(N(CH3)a)b[N(Si(CH3)c)d] is provided.

In accordance with another aspect of the present invention, a depositing method for a dielectric material is provided, where the dielectric material has a first and a second primary elements, and a single precursor includes the first and the second primary elements. The depositing method includes pulsing the single precursor, purging a redundant part of the single precursor, pulsing an oxidant for oxidizing the single precursor, and purging a redundant part of the oxidant.

Preferably, the first primary element is one selected from a group consisting of aluminum, a hafnium and a zirconium.

Preferably, the second primary element is silicon.

Preferably, the single precursor includes the compound of Hf(N(CH₃)ₐ)_{b}[N(Si(CH₃)_{c})_{d}]

Preferably, a is in a range of 1 to 4, b is in a range of 1 to 4, c is in a range of 1 to 4, and d is in a range of 1 to 4.

Preferably, a=2, b=3, c=3 and d=2.

In accordance with a further aspect of the present invention, a single precursor for depositing the dielectric material is provided. The single precursor includes a first primary element and a silicon element, where the first primary element is one selected from a group consisting of aluminum, hafnium and zirconium.

Preferably, the dielectric material is deposited by a method comprising steps of pulsing the single precursor, purging a redundant part of the single precursor, pulsing an oxidant for oxidizing the single precursor, and purging a redundant part of the oxidant.

Preferably, the single precursor has an oxidation product having a metal silicate.

Preferably, the metal silicate comprises a transition metal.

Preferably, the transition metal is one selected from a group consisting of aluminum, hafnium and zirconium.

Preferably, the oxidant is one selected from a group consisting of ozone, oxygen and water.

The above objects and advantages of the present invention will become more readily apparent to those ordinarily skilled in the art after reviewing the following detailed descriptions and accompanying drawings, in which:

### BRIEF DESCRIPTION OF THE DRAWINGS

FIG. 1 is the schematic diagram showing the pulse-purge deposition method;

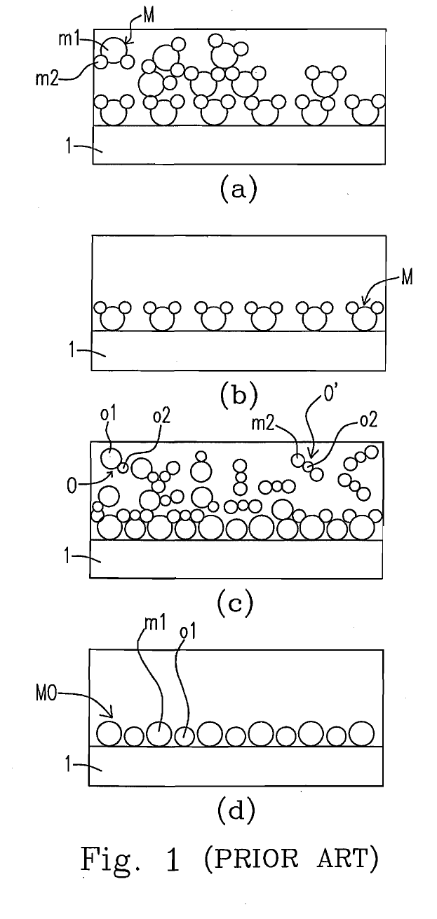

FIG. 2 is the time diagram showing the pulse-purge deposition method;

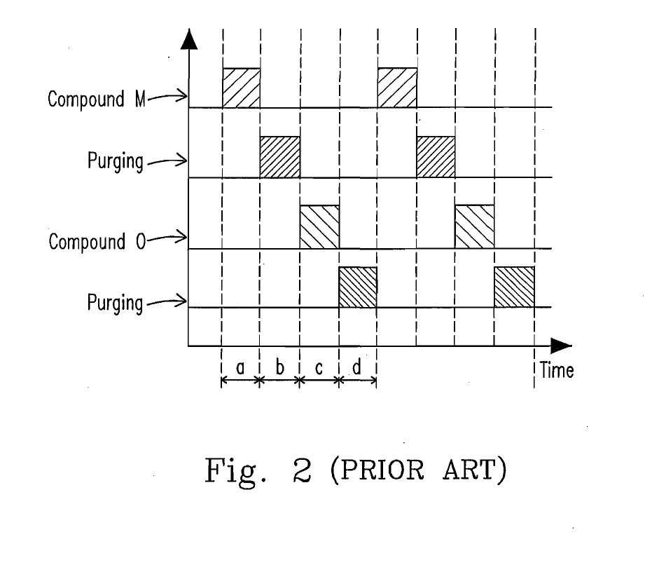

FIG. 3 is the time diagram showing the conventional pulse-purge deposition method; and

FIG. 4 is the time diagram showing the pulse-purge deposition method according to the present invention.

### DETAILED DESCRIPTION OF THE PREFERRED EMBODIMENT

The present invention will now be described more specifically with reference to the accompanying drawings as well as the associated embodiments. It is to be noted that the following descriptions of the preferred embodiments of this invention are presented herein for the purpose of illustration and description only; it is not intended to be exhaustive or to be limited to the precise form disclosed.

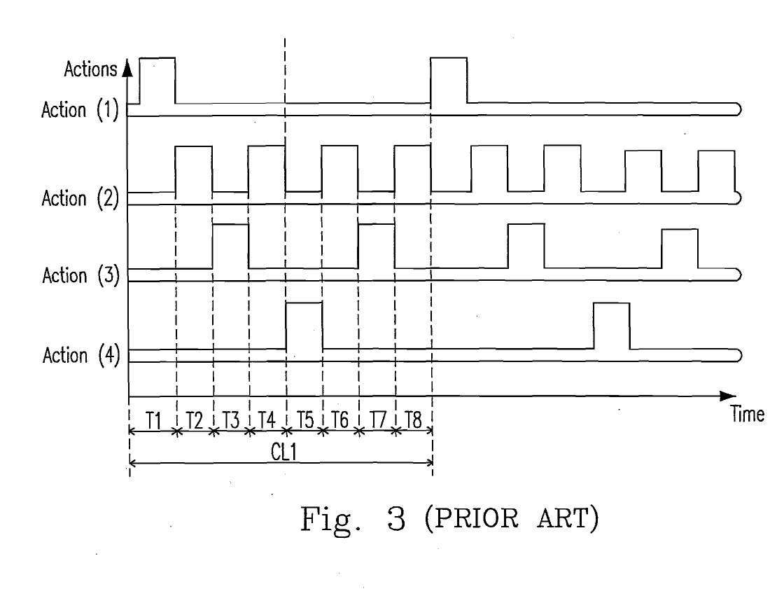

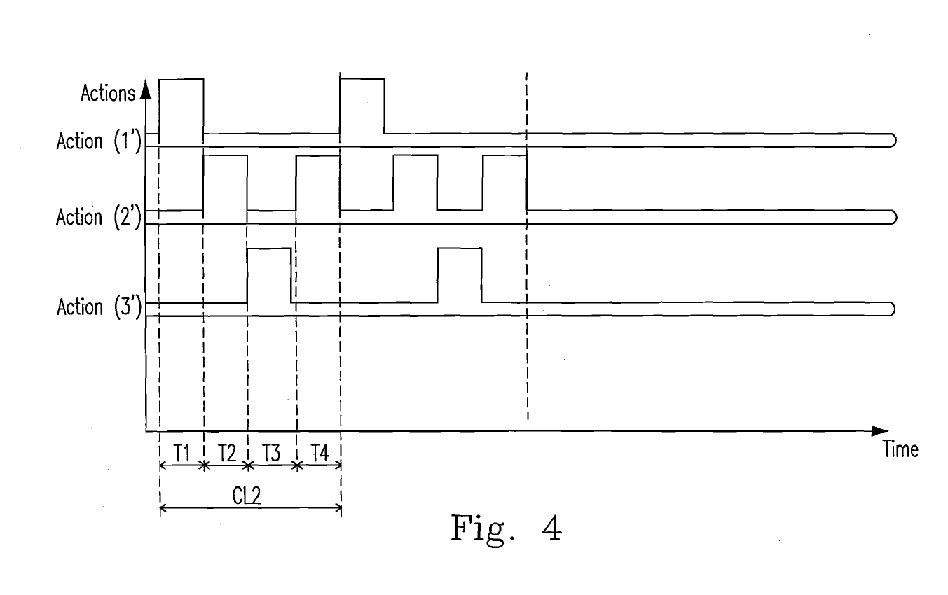

Please refer to FIG. 4, which is the time diagram showing the pulse-purge deposition method according to the present invention, where the X-axis shows the action contents; while the Y-axis indicates the timing. The actions from top to bottom in the X-axis in FIG. 3 are listed in the followings: action (1′): pulsing the first material; action (2′): purging; and the action (3′): pulsing oxidant O. Form the time-frame perspective as shown in FIG. 4, action (1′) is performed in the time period T1, action (2′) is performed in the time period T2, action (3′) is performed in the time period T3, and action (2′) is performed in the time period T4. The time periods from T1 to T4 form a complete cycle, CL2, of the present invention. It takes a long time for the conventional technique due to too many times for the pulse-purge process. Thus, the concept of reducing the times for the pulse-purge process is embodied by combining two precursors through integration, and therefore only one pulse-purge procedure is required to accomplish the deposition for all necessary elements (or compounds). In order to embody this concept, a single precursor instead of the conventional two precursors is introduced at the start of the entire deposition process. The deposition process by using the precursor of the present invention is described as follows. At first, in step (1), a substrate (not shown in FIG. 4) with a deep trench (or stacked) structure is provided. This substrate is similar to or the same as that used in the conventional technique. Then, in step (2), a single precursor instead of conventional two precursors is pulsed on the substrate and deposited on the deep trench (or stacked) structure of the substrate. The precursor of the present invention contains both the first and the second elements, which are originally included in the conventional two precursors, respectively. For the dielectric material containing two primary elements, the hafnium silicate is the most often used, and is obtained from the reactions of two precursors. The two precursors are the precursor of hafnium, i.e. TEMA Hf, Hf[N(C₂H₅)(CH₃)]₄, as the first compound, among which Hafnium is the first primary element, and the precursor of silicon, 3-DMA Si, Si[N(CH₃)₂]₃H, as the second compound, among which silicone is the second primary element. The hafnium silicate formed from the two compounds has high dielectric constant. That is to say, the single precursor of the present invention contains both hafnium and silicon. Then, in step (3), redundant precursor is purged. After then, in step (4), the oxidant is pulsed. Finally, in step (5), the redundant oxidant is purged.

Please refer to FIG. 4 again. The above mentioned step (1) is related to the process before the deposition, and, therefore, is not discussed any further here. To compare step (2) with the showing of FIG. 4, the action (1′) is performed by pulsing the first material in the time period T1. The first material in the action (1′) is the precursor of the present invention. To compare step (3) with FIG. 4, the action (2′) is performed in the time period T2, i.e. purging the redundant precursor in this embodiment. To compare step (4) with FIG. 4, the action (3′) is performed in the time period T3, i.e. pulsing the oxidant. Finally to compare step (5) with FIG. 4, the action (2′) is performed in the time period T4, i.e. purging the redundant oxidant.

Therefore, from the above-mentioned steps and FIG. 4, it can be known that the two pulse-purge processes for the two precursors can be reduced to only one pulse-purge processes by introducing the precursor of the present invention instead of the two precursors as used in the conventional technique. Accordingly, the two pulse-purge processes for pulsing the oxidant twice can be reduced to only one pulse-purge process as well. That is to say, four pulse-purge processes as used in the conventional technique are reduced to two pulse-purge processes for the present invention. Therefore, the precursor of the present invention can reduce almost half the entire processing time. That is, the processing time is decreased from 3 minutes to 90 seconds, so the production throughput becomes double during the same time period, and the high production efficiency can be attained.

Based on the above descriptions and showings of FIG. 4, the actions in FIG. 4 are explained in detail as follows. The action (1′) is performed in the time period T1 by pulsing the first material, i.e. pulsing the precursor. The action (2′) is performed in the time period T2 by purging, i.e. purging the redundant precursor. The action (3′) is performed in the time period T3 by pulsing the oxidant. Finally, the action (2′) is performed in the time period T4 by purging, i.e. purging the redundant oxidant.

From the above description, it can be known that one pulse-purge processes can be eliminated by using the first material, i.e. using the above-mentioned single precursor containing the required first and second primary elements for the dielectric materials. Since the conventional second precursor is not required anymore in the present invention, the oxidant associated with this second precursor is not required, either. Therefore, totally two pulse-purge processes are eliminated by using the present invention. That is, four two pulse-purge processes necessary for the conventional technique are reduced to two pulse-purge processes for the present invention. According, the present invention can save the half of the processing time. In this embodiment, the first primary element can be aluminum, hafnium, or zirconium, while the second primary element can be silicon. The substrate, on which the dielectric material deposit, can contain the deep trench or stacked structure.

For the application of the material with high dielectric constant, specially for the deep trench (or stacked) structure, the metal silicate is often used as a high dielectric-constant material currently. Therefore, the metal silicate is instantiated in another embodiment of the present invention. The deposition method for this dielectric material is described as follows. At first, the precursor of the metal silicate is pulsed. Then, the redundant precursor is purged. After then, the oxidant is pulsed. Finally, the redundant oxidant is purged.

Please refer to FIG. 4 and the above description. The action (1′) is performed in the time period T1 by pulsing the first material, i.e. pulsing the precursor of metal silicate. The action (2′) is performed in the time period T2 by purging, i.e. purging the redundant precursor of metal silicate. The action (3′) in the time period T3 by pulsing the oxidant. Finally, the action (2′) is performed in the time period T4 by purging, i.e. purging the redundant oxidant. From the above description, the metal silicate is directly used as a precursor in this embodiment, thus one pulse-purge process for one of two precursors in the conventional technique is eliminated, and accordingly the pulse-purge process for the oxidant associated with that precursor is eliminated as well, so totally two pulse-purge processes are eliminated. The whole processing time for this embodiment is decreased to half, as compared with the conventional technique. In other words, the production rate is doubled in this embodiment, and this doubled production rate contributes a great benefit in the competitiveness. The metal in the metal silicate can be selected from the transition metal, e.g. hafnium or zirconium. The aluminum silicate can also be chosen as a candidate for the metal silicate. The ozone is often used as the oxidant, while oxygen and water are alternatives.

To sum up, the inventor paid a lot of efforts to develop the present invention by reducing the pulse-purge processes as the concern of too long processing time for the conventional technique. One method to solve this problem is to use a new single precursor, which contains the first primary element in the conventional first precursor and the second primary element in the conventional second precursor. Furthermore, this new precursor adopts the silicate precursor, which has high dielectric constant. This metal silicate precursor can be a compound containing methyl groups, nitrogen, silicon and hafnium, e.g. Hf(N(CH₃)ₐ)_{b}[N(Si(CH₃)_{c})_{d}]. Preferably, the a is in the range of 1 to 4, the b is in the range of 1 to 4, the c is in the range of 1 to 4, and the d is in the range of 1 to 4, such as Hf(N(CH₃)₂)₃[N(Si(CH₃)₃)₂]. The equation of the chemical reaction in the dielectric material deposition is shown below:

Hf(N(CH₃)ₐ)_{b}[N(Si(CH₃)_{c})_{d}]+O₃(or H₂O

→HfₓSi₍ₓ₋₁₎O+CO₂+H₂O+N₂

This precursor is reacted with the oxidant, e.g. ozone or water, to generate hafnium silicate, carbon dioxide, water and nitrogen. It can be seen that using this precursor can reduce the pulse-purge processes for the conventional precursors. Accordingly, the pulse-purge processes for the oxidants associated with the conventional precursors can be reduced as well. Therefore, compared with the conventional technique, the embodiment of the present invention can reduce a half of the whole processes, and consequently the production time is reduced by one half, too. So during the same time period, the production throughput will be doubled by using the precursor provided in the present invention. Moreover, no new machine, no remodeling of the machine, and no change on the machine setting is required for applying the embodiments of the present invention. The original machine is still available for the present invention. Thus, the present invention can greatly reduce the production cost. In conclusion, the present invention can provide great contributions for tremendously increasing the production throughput, largely reducing the production cost, and significantly raising the yield rate.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A depositing method for a dielectric material having a first primary element and a second primary element by introducing a single precursor having the same first primary element and the second primary element, comprising the steps of:
pulsing the single precursor;
purging a redundant part of the single precursor;
pulsing an oxidant for oxidizing the single precursor; and
purging a redundant part of the oxidant.

2. The method according to claim 1, wherein the first primary element is selected from a group consisting of aluminum, hafnium and zirconium.

3. The method according to claim 1, wherein the second primary element is silicon.

4. The method according to claim 2, wherein the single precursor comprises Hf(N(CH₃)ₐ)_{b}[N(Si(CH₃)_{c})_{d}].

5. The method according to claim 4, wherein a is in a range of 1 to 4, b is in a range of 1 to 4, c is in a range of 1 to 4, and d is in a range of 1 to 4.

6. The method according to claim 4, wherein a=2, b=3, c=3 and d=2.

7. The method according to claim 1, wherein the oxidant is selected from a group consisting of ozone, oxygen and water.

8. A single precursor for depositing a dielectric material, comprising a first primary element and a silicon element, wherein the first primary element is one selected from a group consisting of aluminum, hafnium and zirconium.
